(19) United States
(12) Patent Application Publication
(10) Pub. No.: US 2015/0336173 A1
(43) Pub. Date: Nov. 26, 2015

(54) METHOD FOR MANUFACTURING SILVER NANOWIRES USING COPOLYMER CAPPING AGENTS

(71) Applicants: INSCON TECH CO., LTD., Hwaseong-si, Gyeonggi-do (KR); SOLOE TECH CO., LTD., Anseong-si, Gyeonggi-do (KR)

(72) Inventors: Jong Eun KIM, Seoul (KR); Tae Young KIM, Seoul (KR)

(21) Appl. No.: 14/652,083

(22) PCT Filed: Dec. 13, 2013
(86) PCT No.: PCT/KR2013/011586

§ 371 Date: Jun. 12, 2015

(30) Foreign Application Priority Data
Dec. 14, 2012 (KR) 10-2012-0146057

(51) Int. Cl. B22F 9/24; B22F 1/00; C22B 3/00; H01L 29/06

(52) U.S. Cl. CPC B22F 9/24; H01L 29/0669; B22F 1/0044; B22F 1/004; C22B 11/04

(57) ABSTRACT

This invention relates to novel capping agents for manufacturing silver nanowires having a diameter of less than 100 nm and a length of 5 μm or more and, more specifically, to a method of manufacturing silver nanowires and silver nanowires manufactured thereby, wherein the silver nanowires are imparted with a large aspect ratio by using vinylpyrrolidone-co-vinylimidazole copolymers (PIC) as novel capping agents in place of existing capping agents when the silver nanowires are synthesized by mixing and heating (polyol method) a silver salt precursor, a reducing solvent (a reduction agent), and a capping agent. The use of this technique enables the easy synthesis of silver nanowires having a diameter of less than 100 nm and a length of 5 μm or more, with almost no granular silver particles formed during synthesis.

### TECHNICAL FIELD

The present invention relates to a method of manufacturing silver nanowires using a novel capping agent and, more particularly, to a method of uniformly manufacturing silver nanowires having a diameter of less than 100 nm and a length of at least 5 μm, wherein, when silver nanowires are synthesized using a silver salt precursor, a reducing solvent, and a capping agent, a vinylpyrrolidone-co-vinylimidazole copolymer (PIC) is newly adopted as the capping agent.

### BACKGROUND ART

For a variety of electronic devices, including smart phones, tablet computers, etc., so-called touch screens are employed. Such touch screens include transparent electrode films, with a surface resistivity of hundreds of ohm/square (Ω/□) or less and a light transmittance of 90% or more relative to the light transmittance of a base film.

To this end, a currently available transparent electrode material is indium tin oxide (ITO). A transparent electrode film is formed on the surface of glass or a transparent polymer film using a sputtering process so as to impart thereto a surface resistivity of tens to hundreds of Ω/□ and a light transmittance of 90% or more relative to the light transmittance of a base film.

However, the ITO transparent thin film has very high manufacturing cost due to vacuum processing, and is not resistant to external shocks, such as thermal shocks. Hence, many attempts have been made to replace ITO films.

Materials capable of replacing the ITO transparent electrode material include carbon nanotubes, graphene, conductive polymers, and metal nanowires. Among them, metal nanowires are known to possess surface resistivity and light transmittance suitable for use in transparent electrodes when such nanowires, which are manufactured to have a diameter of less than 100 nm and a length of about tens of μm, are provided in the form of a thin film on the surface of a transparent base film. In particular, when a surface resistivity as low as tens of Ω/□ is required, silver nanowires are receiving attention as a novel material having a surface resistivity of tens of Ω/□ or less and a light transmittance of 90% or more relative to the light transmittance of a base film, because the conventional ITO film has low light transmittance.

Silver nanowires are the most useful among metal nanowires. Silver nanowires are known to be manufactured using a so-called polyol method (References: US 2005/0056118, Science 298, 2176, 2002, Chem. Mater. 14, 4736, 2002).

The polyol method enables the formation of silver nanowires having a diameter on the order of nanometers by mixing a silver salt precursor (a metal precursor), a reducing solvent such as ethylene glycol (EG), and a capping agent.

To synthesize a nanostructure in nanowire form from a metal salt precursor including a silver salt, the use of a capping agent is essential. Typical examples of the capping agent include polyethylene oxide, a glucose-based compound, polyvinylpyrrolidone (PVP), and an imidazolium ionic liquid (IL). The most useful capping agents may include polyvinylpyrrolidone and an imidazolium-based ionic liquid. When polyvinylpyrrolidone is used as the capping agent, silver nanowires that are long and have a relatively small diameter may be manufactured, but granular silver particles may be formed together with the nanowires, and thus an additional step must be undertaken to separate the granular silver in order to obtain only nanowires, which is undesirable. On the other hand, when an imidazolium-based ionic liquid is used as the capping agent, the anion component of the ionic liquid may be controlled to synthesize silver nanostructures in diverse forms, such as cubes, octahedra, nanowires, etc. (Reference: Angewandte Chemie, 121, 3864, 2009). In particular, when silver nanowires are manufactured using the ionic liquid as the capping agent, silver nanowires may be manufactured alone, with almost no granular silver, and thus additional processing for separating granular silver is obviated; however, the diameter of the resulting nanowires is slightly large.

As for the synthesis of metal nanowires using silver, there is the need for a novel capping agent able to overcome the drawbacks of existing capping agents such as polyvinylpyrrolidone and an imidazolium-based ionic liquid, and for a method of manufacturing silver nanowires having a diameter of less than 100 nm and a length of at least 5 μm using such a novel capping agent.

### DISCLOSURE

### Technical Problem

Accordingly, an object of the present invention is to provide a technique for reproducibly manufacturing uniform silver nanowires having a diameter of less than 100 nm and a length of 5 μm or more, without any other nanostructure, by use of a polyol reduction reaction using a silver salt precursor.

The objects of the present invention are not limited to the foregoing, and the other objects not mentioned herein will be able to be clearly understood to those skilled in the art from the following description.

### Technical Solution

In order to accomplish the above object, as for the synthesis of silver nanowires by mixing a silver salt precursor, a reducing solvent, and a capping agent, the present inventors have evaluated the effects of various kinds of capping agents on the diameter and the length of synthesized silver nanowires.

Based on the research results, the present inventors have found that, as for the synthesis of silver nanowires by mixing a silver salt precursor (e.g. AgNO₃) and a reducing solvent (e.g. ethylene glycol), acting as main components, with a capping agent, when a copolymer having one or more functional groups is prepared and used as the capping agent, instead of using a conventional polymer composed exclusively of a single component, a combination of the advantageous effects of individual functional groups is exhibited. Specifically, when a copolymer having both a vinylpyrrolidone functional group and a vinylimidazole or vinylimidazolium functional group is used as a capping agent, silver nanowires having a diameter of less than 100 nm and a length of at least 5 μm (mostly 20 μm or more) may be synthesized, with almost no granular silver.

The silver salt precursor is a compound comprising a silver cation and an organic or inorganic anion, and examples thereof may include AgNO₃, AgClO₄, AgBF₄, AgPF₆, CH₃COOAg, AgCF₃SO₃, Ag₂SO₄, and CH₃COCH═COCH₃Ag. The silver salt is dissociated in a solvent and then reduced, and is thus converted into silver metal.

The reducing solvent is a polar solvent able to dissolve the silver salt and refers to a solvent having at least two hydroxyl groups in the molecule thereof, such as diol, polyol, or glycol. Specific examples thereof may include ethylene glycol, 1,2-propylene glycol, 1,3-propylene glycol, glycerin, glycerol, and diethyl glycol. The reducing solvent functions to dissolve the silver salt and also to induce a reduction reaction of the silver cation at a predetermined temperature or higher so as to produce a silver metal element.

For the capping agent, a vinylimidazole-based ionic liquid monomer, a vinylpyrrolidone-based monomer, and an initiator are mixed with a solvent and then heated, yielding a vinylpyrrolidone-co-vinylimidazole copolymer (PIC), which is then utilized as a capping agent for synthesizing silver nanowires.

The imidazole functional group is converted into an imidazolium functional group through a separate reaction, after which the anion component of imidazolium is substituted with a halogen-based component such as chloride or an alkyl sulfate component such as methyl sulfate, thereby synthesizing any type of ionic liquid, which may then be utilized as a capping agent.

The capping agent according to the present invention may include a vinylpyrrolidone-co-vinylimidazole copolymer of Chemical Formula 1 below, a vinylpyrrolidone-co-vinylimidazolium copolymer of Chemical Formula 2 below, or a mixture thereof. The anion of the vinylpyrrolidone-co-vinylimidazolium copolymer of Chemical Formula 2 is an organic or inorganic anion. For the synthesis of silver nanowires, the anion is exemplified by chloride (Cl⁻), or alkyl sulfate such as methyl sulfate (MeSO₄²⁻).

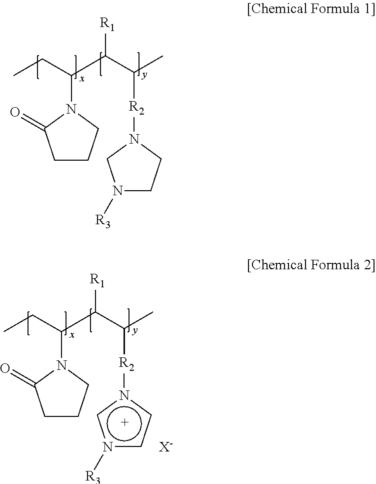

In Chemical Formulas 1 and 2, R₁, R₂, and R₃ are identical to or different from each other, and each represents hydrogen or a hydrocarbon group having 1 to 16 carbon atoms, and may selectively contain at least one heteroatom selected from among oxygen, sulfur, nitrogen, phosphorus, fluorine, chlorine, bromine, iodine, and silicon. In Chemical Formula 2, X⁻ is an anion of an imidazolium-based ionic liquid, such as a halogen anion including Cl⁻, or Br⁻, or an alkyl sulfate component. In Chemical Formulas 1 and 2, x and y are integers.

Chemical Formula 1 represents the vinylpyrrolidone-co-imidazole copolymer, and Chemical Formula 2 represents the vinylpyrrolidone-co-vinylimidazolium copolymer. A specific example of vinylimidazolium may include 1-vinyl-3-alkyl-imidazolium, including 1-vinyl-3-ethylimidazolium, 1-vinyl-3-butylimidazolium, or 1-vinyl-3-hexylimidazolium.

In order to synthesize the nanowires, a halogen-based anion component including chloride (Cl⁻), or an alkyl sulfate component including methyl sulfate, is preferably used as the anion of the copolymer of Chemical Formula 2 comprising 1-vinyl-3-alkyl-imidazolium.

Methods of preparing the vinylpyrrolidone-co-vinylimidazole copolymer and preparing the vinylpyrrolidone-co-vinylimidazolium copolymer therefrom are as follows.

Specifically, vinylpyrrolidone and vinylimidazole are mixed at a predetermined ratio in a reaction solvent, further added with an appropriate amount of reaction initiator, and then heated at 50 to 80° C. for 1 to 24 hr so as to be copolymerized.

The vinylpyrrolidone-co-vinylimidazole copolymer thus obtained is precipitated with a non-solvent, and is then washed with a solvent, yielding a copolymer.

In this reaction, vinylpyrrolidone and vinylimidazole are mixed at a molar ratio ranging from 12:1 to 32:1. If the molar ratio of vinylpyrrolidone and vinylimidazole is less than 12:1, that is, if the amount of vinylimidazole is too high, a silver nanostructure may be synthesized in granular or other form, rather than the wire form, making it impossible to achieve the object of the present invention. In contrast, if the molar ratio thereof exceeds 32:1, that is, if the amount of vinylpyrrolidone is too high, nanowires may be formed, but the diameter thereof may become too thick.

The solvent used to prepare the present copolymer may include any one or a mixture of two or more selected from among alcohol solvents such as methanol, ethanol, propanol, isopropanol, butanol, and isobutanol, aromatic hydrocarbon solvents such as benzene, ethylbenzene, chlorobenzene, toluene, and xylene, aliphatic hydrocarbon solvents such as hexane, heptane, and cyclohexane, and halogenated hydrocarbon solvents such as chloroform, tetrachloroethylene, carbon tetrachloride, dichloromethane, and dichloroethane.

As the reaction initiator, any initiator may be used so long as it reacts with a vinyl group such that polymerization occurs. The reaction initiator may typically include any one or a mixture of two or more selected from among peroxides, azo compounds, and sulfur compounds.

Below is a description of preparation of the vinylpyrrolidone-co-vinylimidazolium copolymer from the vinylpyrrolidone-co-vinylimidazole copolymer obtained as above. Specifically, the prepared vinylpyrrolidone-co-vinylimidazole copolymer is dissolved in a solvent, added with a chloroform solvent, chlorobutane, and diethyl sulfate, and then stirred, so that the imidazole functional group of the copolymer is linked with the anion and is thereby converted into an imidazolium functional group.

As such, to substitute the anion component of the vinylpyrrolidone-co-vinylimidazolium copolymer with another anion, the vinylpyrrolidone-co-vinylimidazolium copolymer is dissolved in a solvent, added with a compound having a desired anion component, and stirred, and thereby may easily possess a desired anion through a so-called ion exchange reaction.

The amount of vinylimidazolium of the vinylpyrrolidone-co-vinylimidazolium copolymer is regarded as an important factor for the synthesis of silver nanowires. However, this amount may be determined upon preparation of the vinylpyrrolidone-co-vinylimidazole copolymer, and thus is not additionally mentioned herein.

The vinylpyrrolidone-co-vinylimidazolium copolymer may be obtained by preparing the vinylpyrrolidone-co-vinylimidazole copolymer and then converting the imidazole functional group into an imidazolium functional group. Alternatively, even when the vinylpyrrolidone-co-vinylimidazolium copolymer is prepared in such a way that vinylimidazole is first converted into vinylimidazolium, the same effects may result. Likewise, the ratio of vinylpyrrolidone to vinylimidazolium may be set within the range from 12:1 to 32:1, as noted above.

A method of manufacturing silver nanowires using the vinylpyrrolidone-co-vinylimidazole or vinylpyrrolidone-co-vinylimidazolium copolymer is specified below. Conventional polyol synthesis method may be used as it is, with the exception that the novel capping agent according to the present invention is used in place of an existing capping agent.

The silver salt precursor, the reducing solvent, and the capping agent of the invention may be mixed at an appropriate ratio, stirred, and reacted at 50 to 180° C. for 30 min to 7 days, thereby manufacturing silver nanowires. When the reaction temperature is low, the period of time required to grow silver nanowires may increase and the reaction time may become long. In contrast, when the reaction temperature is high, silver nanowires may be formed within a relatively short period of time.

In order to uniformly manufacture silver nanowires according to the present invention, the ratios at which the individual components are mixed are regarded as important, and are preferably maintained within the ranges from 1 to 2 mol (4.171 g) of a capping agent and 0.001 to 0.2 mol of an imidazolium-based ionic liquid, based on 1 mol of a silver salt. As such, if the amount of the capping agent is less than 1 mol and the amount of the ionic liquid is less than 0.001 mol, the nanowires may not be uniformly formed, and not only the nanowires but also nanoparticles may be manufactured. In contrast, if the amount of the capping agent exceeds 2 mol and the amount of the ionic liquid exceeds 0.2 mol, the diameter of the nanowires may be increased to 100 nm or more, or silver particles in three-dimensional form, such as granular form, may be obtained, making it difficult to manufacture uniform silver nanowires. In particular, the use of the ionic liquid falling in the range from 0.005 to 0.02 mol is favorable in terms of the formation of more uniform silver nanowires.

The silver nanowires manufactured thereby are filtered using a filtering device, and then washed with a solvent such as water or alcohol. The filtrate of the silver nanowires thus obtained is dispersed in the solvent, thus preparing a silver nanowire dispersion. The solvent for dispersing silver nanowires preferably includes water and an aqueous solvent. Specific examples of the aqueous solvent may include water, alcoholic solvents such as methanol, ethanol, n-propyl alcohol, isopropyl alcohol, n-butanol, isobutanol, hexanol, benzyl alcohol, and diacetone alcohol, polyol-based solvents such as ethylene glycol, propylene glycol, and glycerol, ether-based solvents such as 1,4-dioxane, tetrahydrofuran (THF), ethylene glycol monomethylether, ethylene glycol monoethylether, ethylene glycol dimethylether, propylene glycol monomethylether, propylene glycol monoethylether, and propylene glycol dimethylether, amide-based solvents such as N,N-dimethylformamide, N-methylformamide, and N,N-dimethylacetamide (DMA), nitrile-based solvents such as acetonitrile, and aldehyde-based solvents such as acetaldehyde, and may also include N-methyl-2-pyrrolidone, 2-pyrrolidone, N-vinyl-2-pyrrolidone, dimethylsulfoxide, n-butyrolactone, nitromethane, and ethyl lactate, and these solvents may be used alone or in combination of two or more.

The silver nanowires may be dispersed in the solvent so that the amount thereof is 0.1 to 5 wt %, thereby preparing a silver nanowire dispersion. As necessary, a desired additive, such as a stabilizer including an antioxidant, a dispersant, or a thickener, may be added, in addition to the components for silver nanowires. The additives used to prepare the silver nanowire dispersion may be determined using any technique that is typically carried out by those skilled in the art, and are not limited to special methods.

If the amount of silver nanowires is less than 0.1 wt %, the surface resistivity of the silver nanowires may increase due to an insufficient amount of silver nanowires, or alternatively the wet coating thickness should be increased, undesirably deteriorating coatability or the outward appearance. In contrast, if the amount thereof exceeds 5 wt %, it is difficult to thinly apply the silver nanowires in an excessively high amount, or the silver nanowires in an excessively high amount have to be diluted again in a coating process or a film-forming process.

The silver nanowire dispersion obtained by dispersing the silver nanowires manufactured using the technique of the present invention is applied on a base film and dried, and thereby silver nanowires having a diameter of 100 nm or less and a length of 5 μm or more may be provided in the form of a three-dimensional network film on the surface of the base film.

The base film is a typically useful transparent film and is not limited, and examples thereof may include polyethylene terephthalate, polyethylene naphthalate, polycarbonate, polymethyl methacrylate, polyacrylate, polyacrylonitrile, and polystyrene. Also, to enhance the adhesion between the base film and the silver nanowires, an adhesion-enhancing layer may be applied on the surface of the base film. Alternatively, the surface of the base film may be subjected to corona treatment, plasma treatment, or primer treatment, thereby enhancing adhesion between the silver nanowires and the base film.

The coating process for applying the silver nanowires on the base film may include all known techniques, and typical examples thereof may include dip coating, spin coating, bar coating, gravure coating, reverse gravure coating, offset printing, inkjet printing, spray coating, and slot-die coating, and the coating process is not particularly limited.

As necessary, a dual coating process, which is a conventional technique for coating carbon nanotubes, may be utilized. Specifically, a silver nanowire layer is formed on the surface of a base film, and then a protective layer may be further formed thereon using a separate solution. Any material may be used for the protective layer so long as it has high adhesion to silver nanowires, which make up the lower layer, and has desired properties. Also, this technique is typically carried out by those skilled in the art and is not limited to special methods. The thickness of the protective layer may also be determined using any method that is typically carried out by those skilled in the art.

### Advantageous Effects

According to the present invention, silver nanowires having a diameter of less than 100 nm and a length of at least 5 μm can be uniformly synthesized in a solution phase. The silver nanowires are dispersed in a solvent and then applied on the surface of a base film, thus forming a transparent conductive film, which exhibits a surface resistivity of at least tens of ohm/square and a light transmittance of 90% or more relative to the light transmittance of the base film.

### DESCRIPTION OF DRAWINGS

FIGS. 1 to 8 are scanning electron microscope images illustrating silver nanowires and/or silver nanoparticles according to comparative examples and examples of the present invention.

### MODE FOR INVENTION

A better understanding of the present invention may be obtained via the following examples, which are set forth to illustrate, but are not to be construed as limiting the scope of the present invention.

### Comparative Example 1

### Synthesis of Silver Nanowires Using Polyvinylpyrrolidone

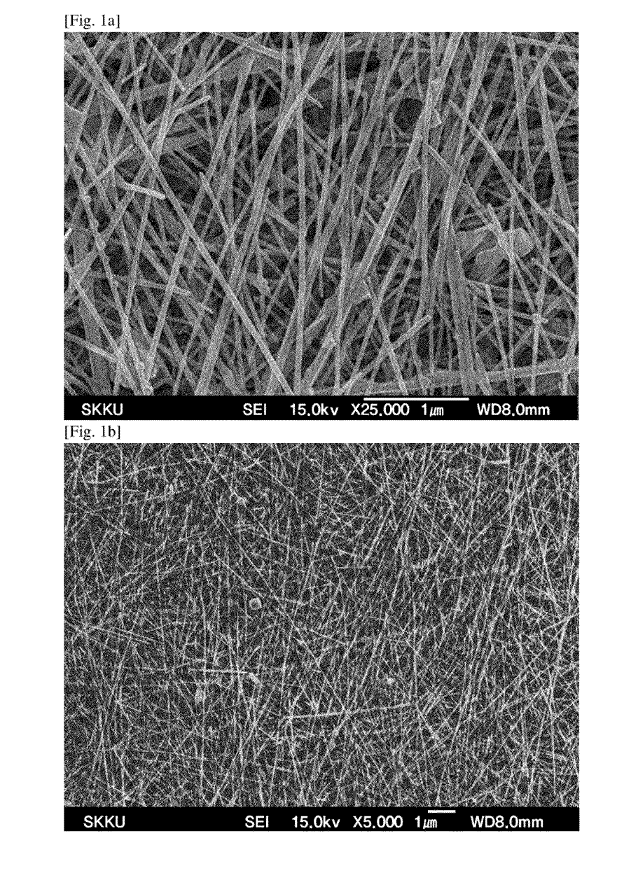

In a 2 L round-bottom flask, 0.1 mol (17 g) of AgNO₃ (made by Kojima, 99.9%) and 0.15 mol (16.7 g) of PVP (made by Aldrich, weight average molecular weight: 55,000 g/mol) were dissolved in 1 L of ethylene glycol (EG) and then stirred at room temperature for 10 min. While the inner temperature of the transparent mixed solution was maintained at 150° C., the reaction was carried out for about 30 min, yielding a taupe solution. This solution was cooled to room temperature, filtered using a filter having 1 μm sized pores, dried, and observed using a scanning electron microscope. As illustrated in the images of FIGS. 1a and 1b, silver nanowires having a diameter of about 90 to 120 nm and a length of 5 to 20 μm were formed, but the diameter of the silver nanowires was slightly large, and was not uniform. Also, not only the silver nanowires, but also silver nanoparticles having a size of about 0.5 to 5 μm were observed.

### Comparative Example 2

### Synthesis of Silver Nanowires Using 1-Butyl-3-Methylimidazolium Methyl Sulfate

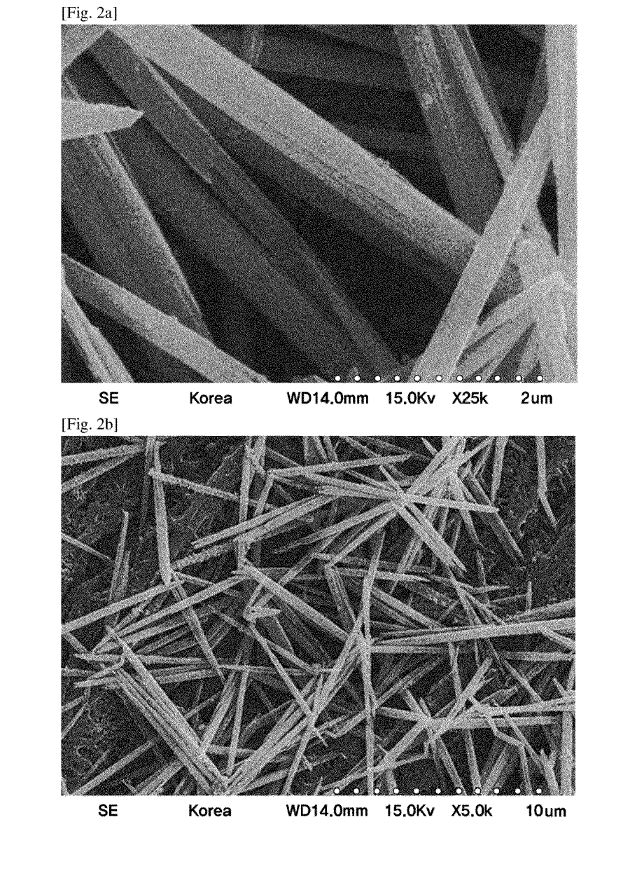

In a 2 L round-bottom flask, 0.063 mol (10.58 g) of AgNO₃ (made by Kojima, 99.9%) and 0.094 mol (23.53 g) of 1-butyl-3-methylimidazolium methyl sulfate (made by Aldrich) were dissolved in 1 L of ethylene glycol (EG) and then stirred at room temperature for 10 min. While the inner temperature of the transparent mixed solution was maintained at 150° C., the reaction was carried out for about 30 min, yielding a taupe solution. This solution was cooled to room temperature, filtered using a filter having 1 μm sized pores, dried, and observed using a scanning electron microscope. As illustrated in the images of FIGS. 2a and 2b, silver nanowires having a diameter of about 200 to 300 nm and a length of about 15 μm were formed.

### Example 1

### Synthesis of Silver Nanowires Using Vinylpyrrolidone(16)-Co-Vinylimidazole(1) Copolymer

Example 1 pertains to the preparation of a vinylpyrrolidone-co-vinylimidazole copolymer comprising vinylpyrrolidone and vinylimidazole at a ratio of 16:1, and also to the synthesis of silver nanowires using such a copolymer.

Preparation of a vinylpyrrolidone-co-vinylimidazole copolymer was conducted as follows.

Vinylpyrrolidone (4.44 g) and vinylimidazole (0.235 g) [vinylpyrrolidone:vinylimidazole=16:1, molar ratio] were added to methanol (40 ml), and about 2% (0.1 g) of azobisisobutyronitrile (AIBN) as an initiator was added to the mixed solution of vinylpyrrolidone and vinylimidazole, followed by mixing at room temperature for 5 min. The resulting mixture was reacted at 75° C. for 7 hr in a nitrogen atmosphere. Thereafter, the mixture was cooled to room temperature and added dropwise to ethyl acetate, so that the reaction product was precipitated. The precipitated white solid was filtered and then dried in a vacuum oven at 30° C. for two days.

Next, the synthesis of silver nanowires using the vinylpyrrolidone-co-vinylimidazole copolymer was conducted as follows.

4.254 g of AgNO₃, 4.171 g of the vinylpyrrolidone-co-vinylimidazole copolymer and 0.131 g of 1-ethyl-3-methylimidazolium chloride (EMIM-Cl) were dissolved in 500 mL of ethylene glycol (PG) and then stirred at room temperature for 10 min. While the inner temperature of the transparent mixed solution was maintained at 90° C., the reaction was carried out for about 24 hr, yielding a gray solution. This solution was cooled to room temperature, filtered using a filter having 1 μm sized pores, dried, and observed using a scanning electron microscope.

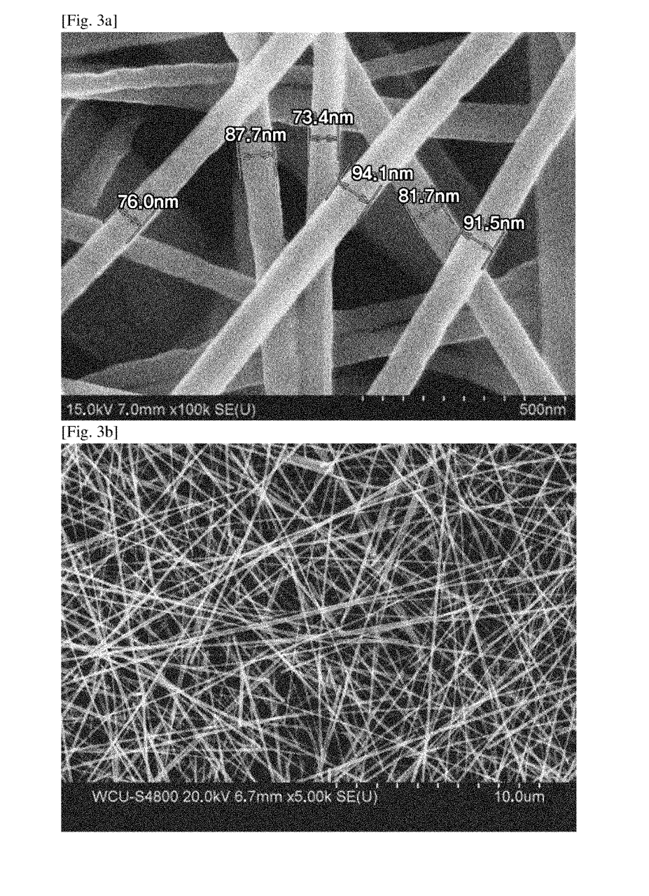

As illustrated in the images of FIG. 3, silver nanowires having a diameter of 80 to 100 nm and a length of 20 to 30 μm were uniformly formed. Unlike the results of Comparative Example 1 using no ionic liquid, only silver nanowires were observed in this example, without silver nanoparticles.

### Example 2

### Synthesis of Silver Nanowires Using vinylpyrrolidone(20)-Co-Vinylimidazole(1) Copolymer

In Example 2, a vinylpyrrolidone-co-vinylimidazole copolymer was prepared in the same manner as in Example 1, with the exception that vinylpyrrolidone and vinylimidazole were used at a ratio of 20:1.

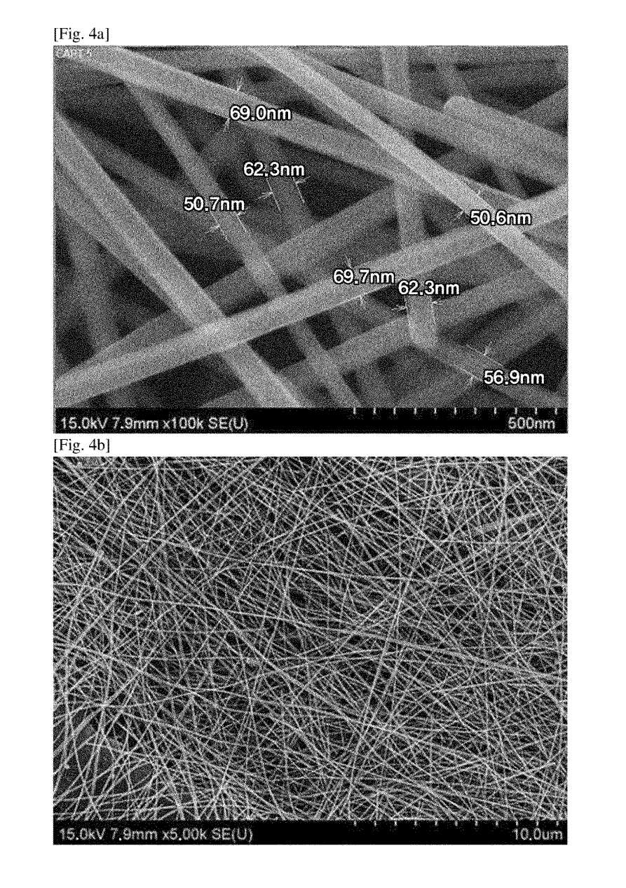

As illustrated in the images of FIG. 4, silver nanowires having a diameter of 55 to 65 nm and a length of 10 to 20 μm were uniformly formed.

### Example 3

### Synthesis of Silver Nanowires Using Vinylpyrrolidone(32)-Co-Vinylimidazole(1) Copolymer

In Example 3, a vinylpyrrolidone-co-vinylimidazole copolymer was prepared in the same manner as in Example 1, with the exception that vinylpyrrolidone and vinylimidazole were used at a ratio of 32:1.

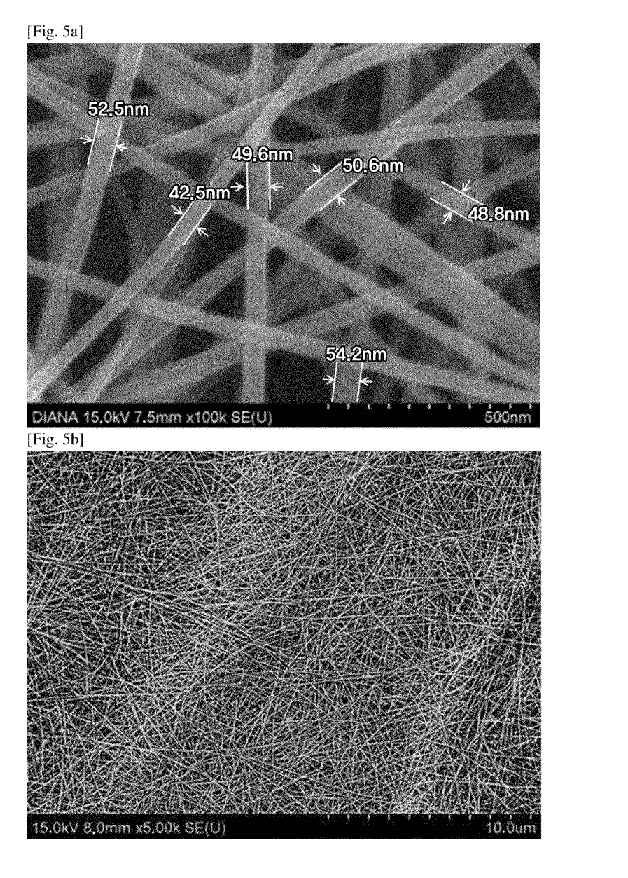

As illustrated in the images of FIG. 5, silver nanowires having a diameter of 50 to 60 nm and a length of 25 to 30 μm were uniformly formed.

### Comparative Example 3

### Preparation of Vinylpyrrolidone(8)-Co-Vinylimidazole(1) Copolymer and Synthesis of Silver Nanowires Using the Same

In Comparative Example 3, a vinylpyrrolidone-co-vinylimidazole copolymer was prepared in the same manner as in Example 1, with the exception that vinylpyrrolidone and vinylimidazole were used at a ratio of 8:1.

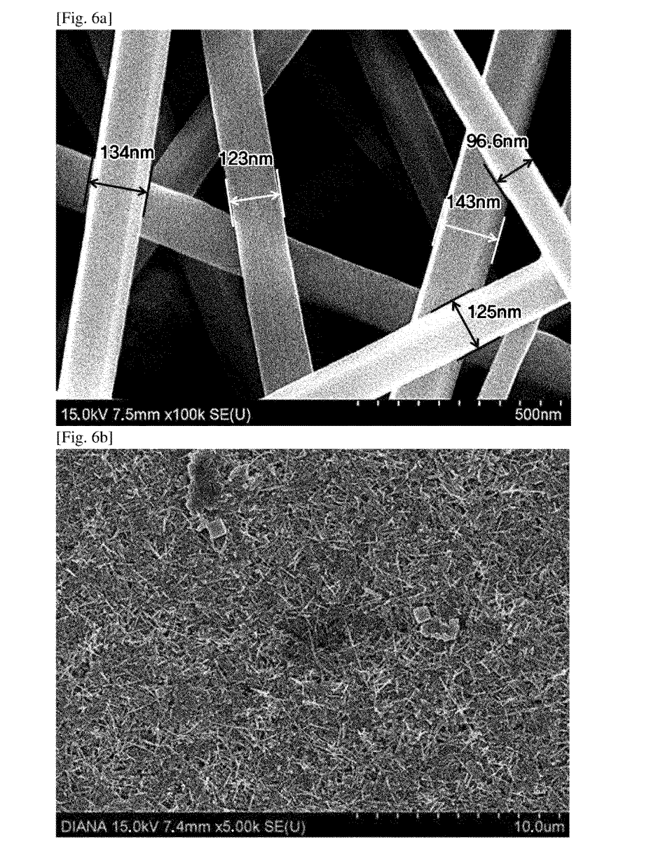

As illustrated in the images of FIG. 6, silver nanowires having a diameter of 100 to 120 nm and a length of 5 to 7 μm were formed. The formation of many particles together with the wires was observed.

### Example 4

### Synthesis of Silver Nanowires Using Vinylpyrrolidone(32)-Co-Vinylimidazolium(1) Chloride Copolymer

Example 4 was performed in the same manner as in Example 3, with the exception that the vinylpyrrolidone(32)-co-vinylimidazolium(1) chloride copolymer, resulting from reacting the vinylpyrrolidone(32)-co-vinylimidazole(1) copolymer prepared in Example 3 with chloroethane, was used.

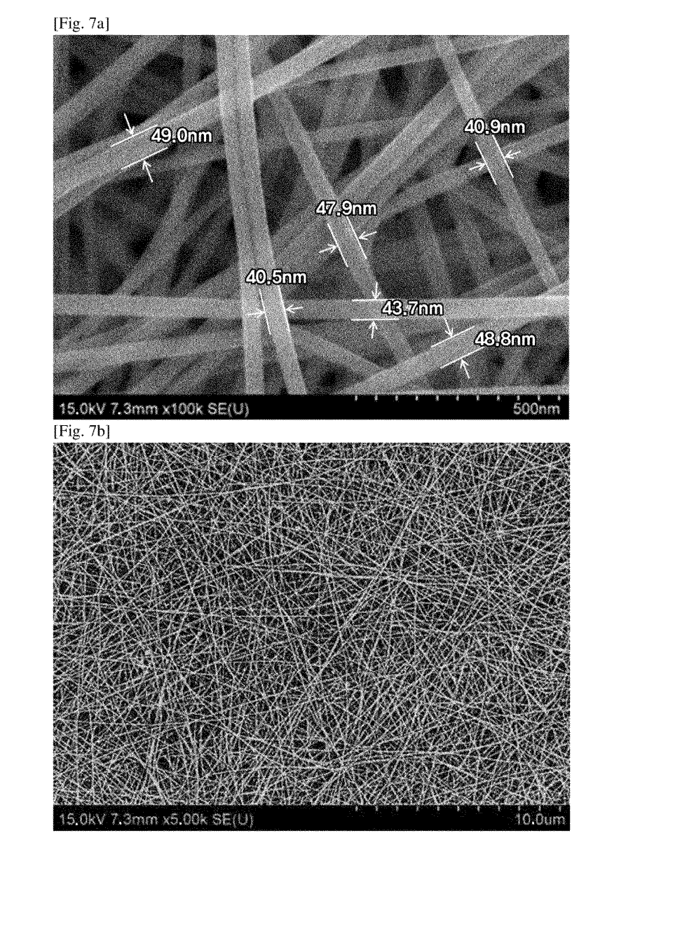

As illustrated in FIG. 7, silver nanowires having a diameter of 50 nm and a length of 30 μm were uniformly formed.

### Example 5

### Synthesis of Silver Nanowires Using Vinylpyrrolidone(32)-Co-Vinylimidazolium(1) Methyl Sulfate Copolymer

Example 5 was performed in the same manner as in Example 3, with the exception that the vinylpyrrolidone(32)-co-vinylimidazolium(1) methyl sulfate copolymer, resulting from reacting the vinylpyrrolidone(32)-co-vinylimidazole(1) copolymer prepared in Example 4 with 1-butyl-3-methylimidazolium methyl sulfate, was used.

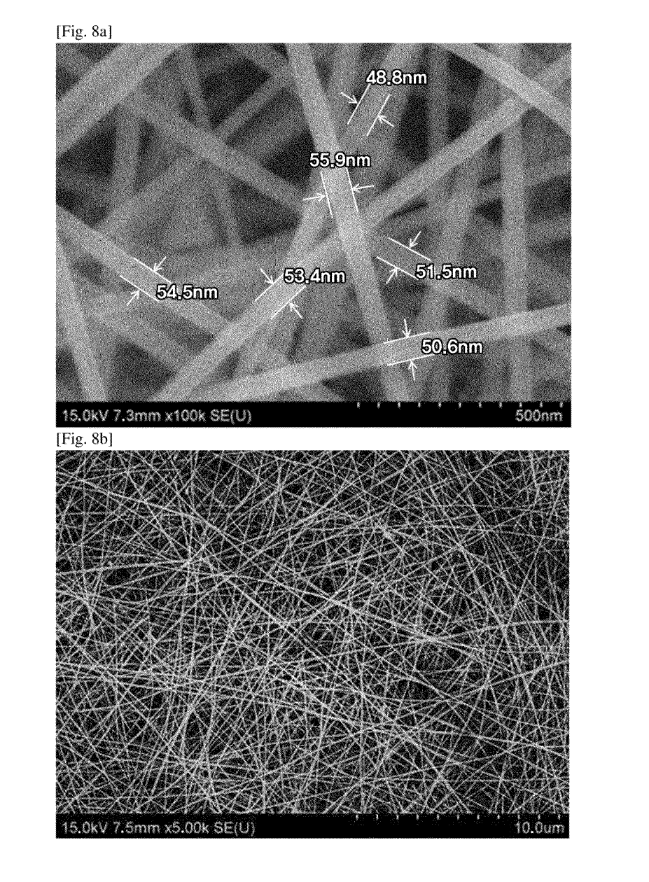

As illustrated in FIG. 8, silver nanowires having a diameter of 50 nm and a length of 30 μm were uniformly formed. Like the results of Example 1, only silver nanowires were observed, without silver nanoparticles.

### INDUSTRIAL APPLICABILITY

According to the present invention, silver nanowires can be utilized in transparent electrode films for so-called touch screens for various electronic devices, including smart phones, tablet computers, etc.

1. A method of manufacturing silver nanowires, comprising subjecting a mixed solution comprising a silver salt precursor, a reducing solvent, and a capping agent to a polyol reduction reaction, wherein the capping agent comprises a copolymer having a vinylpyrrolidone functional group and a vinylimidazole or vinylimidazolium functional group, and
wherein the capping agent comprises a vinylpyrrolidone-co-vinylimidazole copolymer (PIC) obtained by copolymerizing a vinylimidazole-based ionic liquid monomer and a vinylpyrrolidone-based monomer.

2. The method of claim 1, wherein the vinylpyrrolidone and the vinylimidazole are used at a molar ratio ranging from 12:1 to 32:1.

3. (canceled)

4. The method of claim 1 wherein the vinylpyrrolidone-co-vinylimidazole copolymer (PIC) is a vinylpyrrolidone-co-vinylimidazole copolymer of Chemical Formula 1 below, a vinylpyrrolidone-co-vinylimidazolium copolymer of Chemical Formula 2 below, or a mixture thereof: 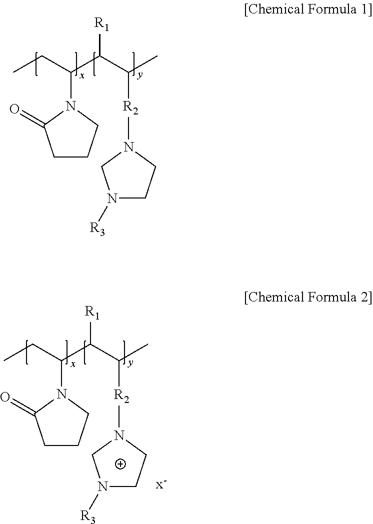
in Chemical Formulas 1 and 2, R₁, R₂, and R₃ are identical to or different from each other, and each represents hydrogen or a hydrocarbon group having 1 to 16 carbon atoms, and selectively contains at least one heteroatom selected from among oxygen, sulfur, nitrogen, phosphorus, fluorine, chlorine, bromine, iodine, and silicon; in Chemical Formula 2, X⁻ is an anion of an imidazolium-based ionic liquid, including a halogen anion including Cl⁻, or Br⁻, or an alkyl sulfate component; and in Chemical Formulas 1 and 2, x and y are integers.

5. The method of claim 4, wherein Chemical Formula 2 represents the vinylpyrrolidone-co-vinylimidazolium copolymer, and the vinylimidazolium is 1-vinyl-3-alkyl-imidazolium, including 1-vinyl-3-ethylimidazolium, 1-vinyl-3-butylimidazolium, or 1-vinyl-3-hexylimidazolium.

6. The method of claim 5, wherein a halogen-based anion component including chloride (Cl⁻), or an alkyl sulfate component including methyl sulfate, is used as an anion of the copolymer of Chemical Formula 2 comprising 1-vinyl-3-alkyl-imidazolium, in order to synthesize the nanowires.

7. The method of claim 1, wherein the mixed solution further comprises an ionic liquid, and 1 to 2 mol of the capping agent and 0.001 to 0.2 mol of the imidazolium-based ionic liquid are used based on 1 mol of the silver salt precursor.

8. The method of claim 7, wherein the silver salt precursor is a compound comprising a silver cation and an organic or inorganic anion, and includes AgNO₃, AgClO₄, AgBF₄, AgPF₆, CH₃COOAg, AgCF₃SO₃, Ag₂SO₄, and CH₃COCH═COCH₃Ag.

9. The method of claim 2, wherein the vinylpyrrolidone-co-vinylimidazole copolymer (PIC) is a vinylpyrrolidone-co-vinylimidazole copolymer of Chemical Formula 1 below, a vinylpyrrolidone-co-vinylimidazolium copolymer of Chemical Formula 2 below, or a mixture thereof: 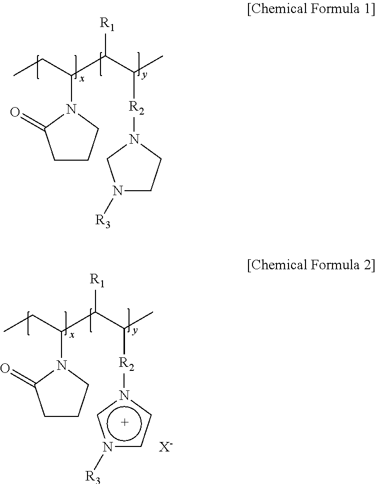
in Chemical Formulas 1 and 2, R₁, R₂, and R₃ are identical to or different from each other, and each represents hydrogen or a hydrocarbon group having 1 to 16 carbon atoms, and selectively contains at least one heteroatom selected from among oxygen, sulfur, nitrogen, phosphorus, fluorine, chlorine, bromine, iodine, and silicon; in Chemical Formula 2, X⁻ is an anion of an imidazolium-based ionic liquid, including a halogen anion including Cl⁻, or Br⁻, or an alkyl sulfate component; and in Chemical Formulas 1 and 2, x and y are integers.

10. The method of claim 9, wherein Chemical Formula 2 represents the vinylpyrrolidone-co-vinylimidazolium copolymer, and the vinylimidazolium is 1-vinyl-3-alkyl-imidazolium, including 1-vinyl-3-ethylimidazolium, 1-vinyl-3-butylimidazolium, or 1-vinyl-3-hexylimidazolium.

11. The method of claim 10, wherein a halogen-based anion component including chloride (Cl⁻), or an alkyl sulfate component including methyl sulfate, is used as an anion of the copolymer of Chemical Formula 2 comprising 1-vinyl-3-alkyl-imidazolium, in order to synthesize the nanowires.

12. The method of claim 2, wherein the mixed solution further comprises an ionic liquid, and 1 to 2 mol of the capping agent and 0.001 to 0.2 mol of the imidazolium-based ionic liquid are used based on 1 mol of the silver salt precursor.

13. The method of claim 4, wherein the mixed solution further comprises an ionic liquid, and 1 to 2 mol of the capping agent and 0.001 to 0.2 mol of the imidazolium-based ionic liquid are used based on 1 mol of the silver salt precursor.

14. The method of claim 5, wherein the mixed solution further comprises an ionic liquid, and 1 to 2 mol of the capping agent and 0.001 to 0.2 mol of the imidazolium-based ionic liquid are used based on 1 mol of the silver salt precursor.

15. The method of claim 6, wherein the mixed solution further comprises an ionic liquid, and 1 to 2 mol of the capping agent and 0.001 to 0.2 mol of the imidazolium-based ionic liquid are used based on 1 mol of the silver salt precursor.

16. The method of claim 9, wherein the mixed solution further comprises an ionic liquid, and 1 to 2 mol of the capping agent and 0.001 to 0.2 mol of the imidazolium-based ionic liquid are used based on 1 mol of the silver salt precursor.

17. The method of claim 10, wherein the mixed solution further comprises an ionic liquid, and 1 to 2 mol of the capping agent and 0.001 to 0.2 mol of the imidazolium-based ionic liquid are used based on 1 mol of the silver salt precursor.

18. The method of claim 11, wherein the mixed solution further comprises an ionic liquid, and 1 to 2 mol of the capping agent and 0.001 to 0.2 mol of the imidazolium-based ionic liquid are used based on 1 mol of the silver salt precursor.

19. The method of claim 12, wherein the silver salt precursor is a compound comprising a silver cation and an organic or inorganic anion, and includes AgNO₃, AgClO₄, AgBF₄, AgPF₆, CH₃COOAg, AgCF₃SO₃, Ag₂SO₄, and CH₃COCH═COCH₃Ag.

20. The method of claim 13, wherein the silver salt precursor is a compound comprising a silver cation and an organic or inorganic anion, and includes AgNO₃, AgClO₄, AgBF₄, AgPF₆, CH₃COOAg, AgCF₃SO₃, Ag₂SO₄, and CH₃COCH═COCH₃Ag.

21. The method of claim 16, wherein the silver salt precursor is a compound comprising a silver cation and an organic or inorganic anion, and includes AgNO₃, AgClO₄, AgBF₄, AgPF₆, CH₃COOAg, AgCF₃SO₃, Ag₂SO₄, and CH₃COCH═COCH₃Ag.
